(19) United States
(12) Patent Application Publication
(10) Pub. No.: US 2008/0156637 A1
(43) Pub. Date: Jul. 3, 2008

(54) METHOD FOR FORMING PHOTOELECTRIC CONVERSION SUBSTRATE

(75) Inventors: Hung-Chang Chen, Tu-Chen City (TW); Wen-Ting Lin, Caotun Township (TW); Wen-Hsien Ho, Keelung City (TW); Masakazu Anpo, Izumisano-City (JP)

Correspondence Address: OCCHIUTI ROHLICEK & TSAO, LLP, 10 FAWCETT STREET, CAMBRIDGE, MA, 02138, US

(73) Assignee: Taiwan Textile Research Institute, Tu-Chen City (TW)

(21) Appl. No.: 11/964,218

(22) Filed: Dec. 26, 2007

(30) Foreign Application Priority Data
Dec. 28, 2006 (TW) 095149541

(51) Int. Cl. C23C 14/35; C23C 14/08

(52) U.S. Cl. 204/192.14; 204/192.15

(57) ABSTRACT

A method for forming photoelectric conversion substrate is provided. First, a conductive substrate is fixed onto a base in a vacuum chamber having a TiO₂ target therein. After that, the vacuum chamber is heated so that the temperature therein is kept between 70˜100° C. Then, a plasma gas consisting of argon and oxygen is filled into the vacuum chamber. The filling pressure of the plasma gas is in the range of 1˜10 Pa and the flow ratio of argon to oxygen thereof is in the range of 9:1˜7:1. Finally, an anatase TiO₂ layer is formed on the conductive substrate by sputtering. A method for manufacturing a dye-sensitized solar cell is also disclosed in the specification.

### RELATED APPLICATIONS

This application claims priority to Taiwan Application Serial Number 95149541, filed Dec. 28, 2006, which is herein incorporated by reference.

### BACKGROUND

1. Field of Invention

The present invention relates to a method for forming a substrate. More particularly, the present invention relates to a method for forming a photoelectric conversion substrate.

2. Description of Related Art

Fossil fuels are still the main energy source used by mankind. However, human activities in pursuit of energy supply have resulted in the rapid depletion of these limited natural resources. On the other hand, the burning of fossil fuels releases carbon dioxide and other pollutants into the atmosphere which is the main reason resulting in greenhouse effect and air pollution. Therefore, there is an imminent need to develop a renewable and environmentally-friendly energy.

Solar energy is energy derived from natural processes and could be replenished constantly. Scientists are dedicated in developing solar cells of a variety of materials, so that the solar cells could be used in different electric appliances and consumer electronic products. One type of the solar cell being investigated is the dye-sensitized solar cell (DSSC). DSSC comprises a photoelectric conversion substrate consisting of an anatase TiO₂ layer and a conductive substrate. Typically, the TiO₂ layer of the photoelectric conversion substrate is formed on the conductive substrate by coating in conjunction with high-temperature sintering or sputtering process. Generally, during the process of high-temperature sintering, the temperature is usually higher than 400° C. so that an anatase TiO₂ could be formed. In respect of the known sputtering process of TiO₂, the temperature of the conductive substrate being processed is usually higher than 200° C. In the above-described cases, when it is desired to fabricate a flexible solar cell, the excessively high temperature involved in the process of forming the TiO₂ layer limits the alternatives of the plastic materials for conductive substrate, thereby increases the difficulties of the fabrication of the flexible solar cell. Therefore, it is desired to provide a method for forming a photoelectric substrate at a lower temperature.

### SUMMARY

The present invention provides a method for forming a photoelectric conversion substrate.

According to one example of the present invention, a method for forming a photoelectric conversion substrate is provided. First, a conductive substrate is fixed onto a base in a vacuum chamber having a TiO₂ target therein. After that, the vacuum chamber is heated and the temperature therein is kept between 70˜100° C. Then, a plasma gas consisting of argon and oxygen is filled into the vacuum chamber. The filling pressure of the plasma gas is 1˜10 Pa and the flow ratio of argon to oxygen thereof is in the range of 9:1˜7:1. Finally, an anatase TiO₂ layer is formed on the conductive substrate by sputtering.

According to another example of the present invention, a method for fabricating a dye-sensitized solar cell is also provided. First, a photoelectric conversion substrate is formed using the method described in the previous example. Then, a dye layer is formed on the photoelectric conversion substrate. Thereafter, the second substrate having the second electrode is overlaid over the photoelectric conversion substrate, wherein the second electrode of the second substrate is facing the photoelectric conversion substrate, and a space is formed between the second electrode and the dye layer. Lastly, an electrolyte is filled into the space between the second electrode and the dye layer, and a dye-sensitized solar cell is formed by a encapsulating process.

According to the method of the examples of the present invention, during the process of forming the TiO₂ layer, the temperature of the conductive substrate is lower than 150° C. As compared to known methods for forming the TiO₂ layer, the method of the present invention renders it possible to choose the material of the conductive substrate from a broader extent, for example, a plastic conductive substrate with lower thermal tolerance could be chosen. Through the use of the plastic conductive substrate, it is possible to form a flexible photoelectric conversion substrate for fabricating a flexible solar cell.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a flow chart illustrating the process for forming a photoelectric conversion substrate according to one example of the present invention;

FIG. 2 is a schematic diagram illustrating the sputtering apparatus for forming the photoelectric conversion substrate;

FIGS. 3A˜3C are schematic diagrams illustrating the process steps for fabricating a dye-sensitized solar cell according to another example of the present invention;

FIG. 4 illustrates the thin film X-ray diffraction diagram of the photoelectric conversion substrate of the example of the present invention;

FIG. 5 illustrates the current-voltage curve of the dye-sensitized solar cell of the example of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

### Method for Forming a Photoelectric Conversion Substrate

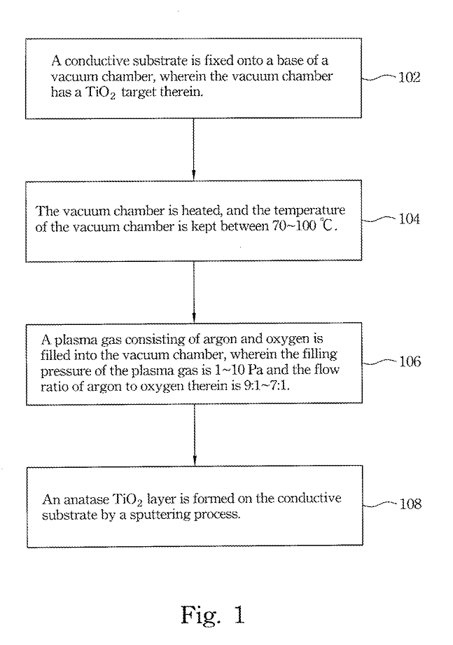

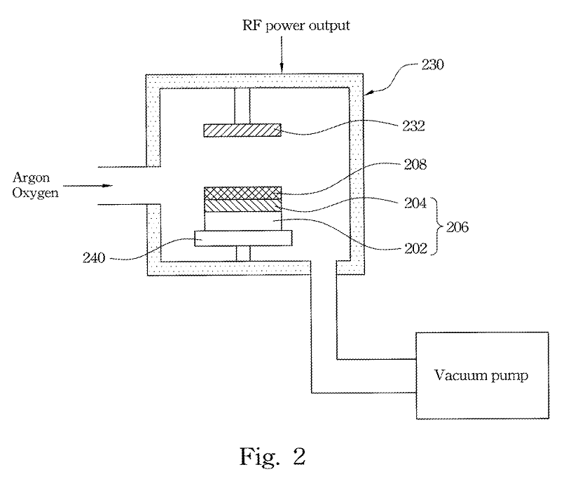

FIG. 1 is a flow chart illustrating the process for forming a photoelectric conversion substrate according to one example of the present invention. FIG. 2 is a schematic diagram illustrating the sputtering apparatus for the forming process of FIG. 1. Please refer to FIGS. 1 and 2. In step 102, a conductive substrate 206 consisting of a first substrate 202 and a first electrode 204 is fixed onto a base 240 of a vacuum chamber 230, wherein the vacuum chamber 230 has a TiO₂ target 232 therein. Thereafter, in step 104, the vacuum chamber 230 is heated, and the temperature of the vacuum chamber 230 is kept between 70˜100° C. Then, in step 106, a plasma gas consisting of argon and oxygen is filled into the vacuum chamber 230, wherein the filling pressure of the plasma gas is 1˜10 Pa and the flow ratio of argon to oxygen therein is 9:1˜7:1. Lastly, in step 108, an anatase TiO₂ layer 208 is formed on the conductive substrate 206 by a sputtering process.

During the process of sputtering, in order to keep the temperature of the conductive substrate 206 lower than 150° C. and form an anatase TiO₂ layer 208 thereon, the parameters of the sputtering process, for example, the selection of the TiO₂ target, the control of the filling pressure and the composition of the plasma gas, and the setting of the heating temperature of the vacuum chamber could be adjusted. In known TiO₂ sputtering processes for forming a photoelectric conversion substrate, the temperature of the conductive substrate is excessively high, i.e., higher than 200° C. It should be appreciated that the method for forming the photoelectric conversion substrate according to the examples of the present invention renders it possible to choose the material of the conductive substrate 206 from a broader extent, for example, a plastic conductive substrate with lower thermal tolerance could be chosen. Through the use of the plastic conductive substrate, it is possible to form a flexible photoelectric conversion substrate for fabricating a flexible solar cell.

Refer to FIG. 2 again, the sputtering process for forming a TiO₂ layer 208 could be a radio frequency magnetron sputtering process. The duration of the sputtering process is 1˜24 hours. The distance between the TiO₂ target 232 and the conductive substrate 206 is 80˜100 mm. The TiO₂ layer 208 is formed on a first electrode 204, wherein the thickness of the TiO₂ layer 208 is 0.4˜10 μm. The first substrate 202 is a plastic substrate. The material of the first substrate 202 is one selected from the group consisting of a polyethylene naphthalate (polyethylene naphthalate; PEN), a poly carbonate (poly carbonate; PC), and a polyethylene terephthalate (Polyethylene terephthalate; PET), so that the photoelectric conversion substrate formed is flexible.

### Method for Forming a Dye-Sensitized Solar Cell

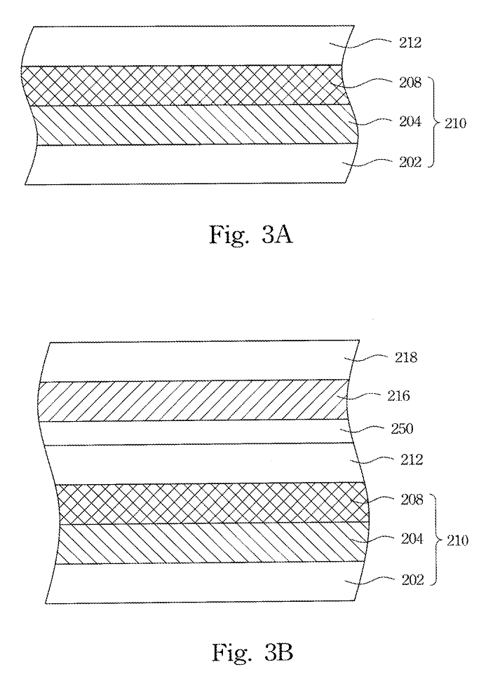

Please refer to FIGS. 3A˜3C, which are schematic diagrams illustrating the process steps for fabricating a dye-sensitized solar cell according to another example of the present invention. In FIG. 3A, a dye layer 212 is formed on a photoelectric conversion substrate 210 of the above-described example. The method for forming the dye layer 212 could be, for example, soaking the photoelectric conversion substrate 210 in a dye. Then, as shown in FIG. 3B, a second substrate 218 having a second electrode 216 is overlaid over the photoelectric conversion substrate 210, wherein the second electrode 216 of the second substrate 218 faces the photoelectric conversion substrate 210. In addition, during the process of overlaying, a seal, for example, could be applied to the circumference of the second substrate 218, so that a space 250 exists between the second electrode 216 and the photoelectric conversion substrate 210, and an aperture is left in the seal. Lastly, an electrolyte 214 is injected into the space 250 between the second electrode 216 and the photoelectric conversion substrate 210 through the aperture, and a dye-sensitized solar cell of FIG. 3C is formed by a encapsulating process.

Refer to FIG. 3C again, the second substrate 218 could be a flexible substrate, and the material thereof could be a polyethylene naphthalate, a poly carbonate, or a polyethylene terephthalate. The second electrode 216 could be a metal electrode or a carbon electrode. The electrolyte 214 could be quaternary ammonium iodized salt or lithium-iodine salt dissolved in high polar organic solvent such as an acetonitrile or a 3-methoxy propionitrile. The material of the dye layer 212 could be, for example, a transition metal organic dye.

### The Crystalline Phase Analysis of the Photoelectric Conversion Substrate and the Current-Voltage Curve of DSSC

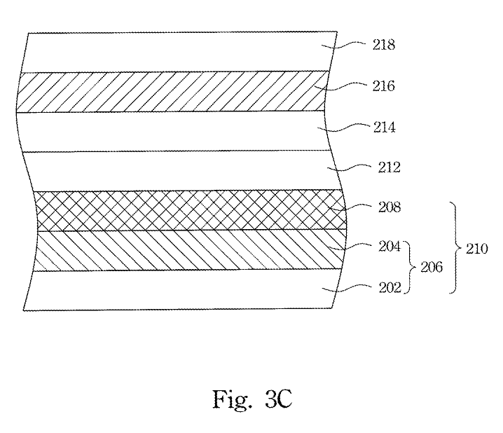

FIG. 4 illustrates a thin film X-ray diffraction diagram of photoelectric conversion substrate according to the examples described, wherein the material of the first substrate is a polyethylene naphthalate (PEN), the first electrode is an indium tin oxide(ITO) and the thickness of the TiO₂ layer thereon is 3˜4 μm. The filling pressure of the plasma gas is 3 Pa, and the gas consists of argon and oxygen with the flow ratio of argon to oxygen being 8:1. The heating temperature of the chamber is 80° C., and during the whole sputtering process the temperature of the conductive substrate is lower than 150□. It could be seen from FIG. 4, the crystalline phase of the TiO₂ layer on the photoelectric conversion substrate is an anatase phase. The photoelectric conversion substrate having such anatase phase could be used in fabricating a dye-sensitized solar cell.

Said photoelectric conversion substrate could be soaked in a dye N719 [cis-bis(isothiocyanato)bis(2,2′-bipyridyl-4,4′-dicarboxylato)-ruthenium(II) bis-tetrabutylammonium] for 24 hours for subsequent process for fabricating a dye-sensitized solar cell. The electrolyte used for this dye-sensitized solar cell is an acetonitrile solution including 0.5M lithium iodide, 0.05M iodine, and 0.5M TBP (4-tert-butylpyridine). The second electrode is a Pt electrode.

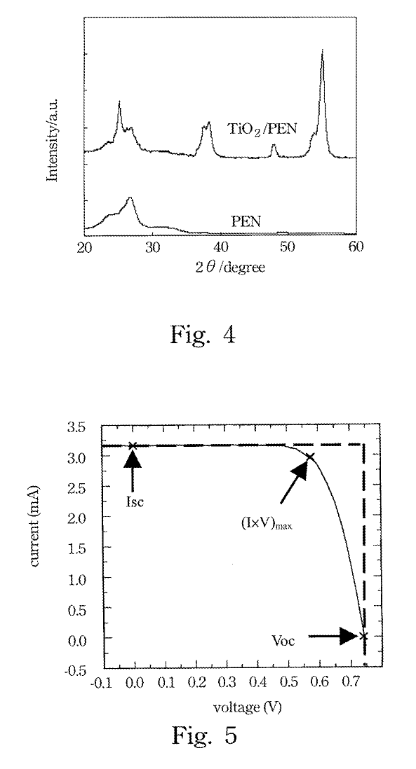

FIG. 5 illustrates the current-voltage curve of this dye-sensitized solar cell. Table 1 lists the data of the performance of this solar cell. In table 1, the maximum power of this solar cell is the product of the open circuit voltage (V_{OC}), the short circuit current (I_{SC}) and the fill factor, and the efficiency of its photoelectric conversion is the maximum power divided by the light intensity, wherein the definition of the fill factor is

$$Fill Factor = \frac{{( V \times I )}_{max}}{( {V}_{oc} \times {I}_{sc} )}$$

It could be seen from table 1, according to the example of the present invention, the photoelectric conversion substrate is formed in low-temperature sputtering. The dye-sensitized solar cell fabricated using such photoelectric conversion substrate possesses the photoelectric conversion ability.

TABLE 1
The performance of the dye-sensitized solar cell

| | Open | | | Efficiency of the |
|---|---|---|---|---|
| | Circuit | Short Circuit | | Photoelectric |
| Light Intensity | Voltage; | current; I_{sc} | | Conversion |
| (W/m²) | V_{OC} (V) | (mA/cm²) | Fill Factor | (%) |
| 100 | 0.63 | 1.00 | 0.38 | 2.41 |
| 100 | 0.66 | 1.17 | 0.39 | 3.03 |

It will be apparent to those skilled in the art that various modifications and variations can be made to the structure of the present invention without departing from the scope or spirit of the invention. In view of the foregoing, it is intended that the present invention cover modifications and variations of the present invention provided they fall within the scope of the following claims.

What is claimed is:

1. A method for forming a photoelectric conversion substrate, the method comprising:
fixing a conductive substrate on to a base in a vacuum chamber, wherein the vacuum chamber having TiO₂ target therein;
heating the vacuum chamber and the temperature of the vacuum chamber being kept between 70˜100° C.;
filling a plasma gas consisting of argon and oxygen into the vacuum chamber, wherein a filling pressure is in the range of 1˜10 Pa, and a flow ratio of argon to oxygen is in the range of 9:1 to 7:1; and
forming an anatase TiO₂ layer on the conductive substrate by a sputtering process.

2. The method of claim 1, wherein the distance between the TiO₂ target and the conductive substrate is 80˜100 mm.

3. The method of claim 1, wherein the conductive substrate comprising:
a first substrate; and
a first electrode positioned at a face of the first substrate facing the TiO₂ layer.

4. The method of claim 3, wherein a material of the first substrate is one selected from the group consisting of a polyethylene naphthalate, a poly carbonate, and a polyethylene terephthalate.

5. The method of claim 1, wherein the filling pressure of the plasma gas is 1˜3 Pa.

6. The method of claim 1, wherein the flow ratio of argon to oxygen is about 8:1.

7. The method of claim 1, wherein the sputtering process is a radio frequency magnetron sputtering.

8. The method of claim 1, wherein the thickness of the TiO₂ layer is 0.4˜10 μm.

9. The method of claim 1, wherein the thickness of the TiO₂ layer is 3˜4 μm.

10. The method of claim 1, wherein the duration of the sputtering process is 1˜24 hours.

11. A method for fabricating a dye-sensitized solar cell, the method comprising:
forming a photoelectric conversion substrate using the method of any one of the claims 1 to 10;
forming a dye layer on the photoelectric conversion substrate;
overlaying a second substrate having a second electrode over the photoelectric conversion substrate, wherein the second electrode of the second substrate faces the photoelectric conversion substrate and there is a space between the second electrode and the dye layer;
filling an electrolyte into the space between the second electrode and the dye layer; and
forming a dye-sensitized solar cell by a encapsulating process.

12. The method of claim 11, wherein a method for forming the dye layer comprising soaking the photoelectric conversion substrate in a dye.

13. The method of claim 11, wherein the second substrate is a flexible substrate.

14. The method of claim 13, wherein a material of the flexible substrate is one selected from the group consisting of a polyethylene naphthalate, a poly carbonate, and a polyethylene terephthalate.
